(19) United States
(12) Patent Application Publication
(10) Pub. No.: US 2014/0310895 A1
(43) Pub. Date: Oct. 23, 2014

(54) SCRUBBER BRUSH FORCE CONTROL ASSEMBLIES, APPARATUS AND METHODS FOR CHEMICAL MECHANICAL POLISHING

(71) Applicant: APPLIED MATERIALS, INC., Santa Clara, CA (US)

(72) Inventor: Hui Chen, Burlingame, CA (US)

(73) Assignee: Applied Materials, Inc., Santa Clara, CA (US)

(21) Appl. No.: 13/866,407

(22) Filed: Apr. 19, 2013

(51) Int. Cl. H01L 21/67; H02P 29/00; H05K 13/00

(52) U.S. Cl. CPC H01L 21/67092; H05K 13/00; H02P 29/00
USPC 15/21.1; 29/825; 318/9

(57) ABSTRACT

A control assembly that may be used with a chemical mechanical polishing (CMP) cleaning unit may include a linkage arm that extends and retracts, a load cell sensor that senses a force on the linkage arm, and a motor. The motor may drive the linkage arm to an extended or retracted position to cause a scrubber brush assembly of the cleaning unit to move away from or into contact with a substrate to be cleaned. In response to a force sensed by the load cell sensor, the motor may adjust the position of the linkage arm to cause an adjustment of the scrubber brush assembly position relative to the substrate being cleaned. Methods of controlling a scrubber brush force are also provided, as are other aspects.

### FIELD

The invention relates generally to semiconductor device manufacturing, and more particularly to substrate cleaning in chemical mechanical polishing.

### BACKGROUND

Chemical mechanical polishing (CMP), also known as chemical mechanical planarization, is a process typically used in the fabrication of integrated circuits on a semiconductor substrate. A CMP polishing process may remove topographic features and materials from a partially-processed substrate to produce a flat surface for subsequent processing. A CMP polishing process may use abrasives and/or a chemically-active polishing solution on one or more rotating polishing pads pressed against a surface of a substrate. A CMP cleaning process may follow a CMP polishing process to remove residual polishing solution and/or particles left on the substrate.

A CMP cleaning process may include scrubbing front and back surfaces of a substrate with scrubber brushes. A force may be applied to the scrubber brushes to produce a desired scrubbing pressure against the substrate. However, too much force can damage the substrate, while too little force can render the cleaning ineffective. Also, because scrubber brush dimensions may change due to brush shrinkage or swelling, the amount of force applied to scrubber brushes may need to change during a CMP cleaning process. Therefore, a need exists to provide accurate monitoring and control of forces applied to scrubber brushes during a CMP cleaning process.

### SUMMARY

According to one aspect, a control assembly for a cleaning unit is provided. The control assembly comprises a linkage arm configured to extend and retract and configured to be coupled to a positioning assembly of the cleaning unit, a load cell sensor coupled to the linkage arm and configured to sense a force on the linkage arm, and a motor configured to drive the linkage arm to extend and retract.

According to another aspect, a method of controlling a scrubber brush force is provided. The method comprises providing a linkage arm configured to extend and retract, providing a load cell sensor coupled to the linkage arm and configured to sense a force on the linkage arm, and providing a motor configured to drive the linkage arm to extend and retract.

According to a further aspect, another method of controlling a scrubber brush force is provided. The method comprises receiving a substrate in a cleaning unit, driving a linkage arm to a first position configured to position a scrubber brush against the substrate, sensing a force on the linkage arm with a load cell sensor, transmitting one or more electrical signals representing the force sensed on the linkage arm, and receiving one or more control signals in response to the transmitting of the one or more electrical signals.

Still other aspects, features, and advantages of the invention may be readily apparent from the following detailed description wherein a number of example embodiments and implementations are described and illustrated, including the best mode contemplated for carrying out the invention.

The invention may also include other and different embodiments, and its several details may be modified in various respects, all without departing from the scope of the invention. Accordingly, the drawings and descriptions are to be regarded as illustrative in nature, and not as restrictive. The drawings are not necessarily drawn to scale. The invention covers all modifications, equivalents, and alternatives falling within the scope of the invention.

### BRIEF DESCRIPTION OF DRAWINGS

The drawings, described below, are for illustration purposes only. The drawings are not intended to limit the scope of the invention in any way.

FIG. 1 illustrates a schematic top view of a cleaning module according to the prior art.

FIG. 2 illustrates a schematic cross-sectional side view of brush box unit according to embodiments.

FIGS. 3A and 3B illustrate schematic top views of the brush box unit of FIG. 2 with scrubber brushes in retracted and cleaning positions, respectively, according to embodiments;

FIG. 4 illustrates a schematic partial right side view of the positioning assembly of the brush box unit of FIG. 2 according to embodiments.

FIGS. 5A and 5B illustrate front and back perspective views, respectively, of a control assembly according to embodiments.

FIG. 6 illustrates a flowchart of a method of controlling a scrubber brush force according to embodiments.

FIG. 7 illustrates a flowchart of another method of controlling a scrubber brush force according to embodiments.

### DETAILED DESCRIPTION

Reference will now be made in detail to the example embodiments of this disclosure, which are illustrated in the accompanying drawings. Wherever possible, the same reference numbers will be used throughout the drawings to refer to the same or like parts.

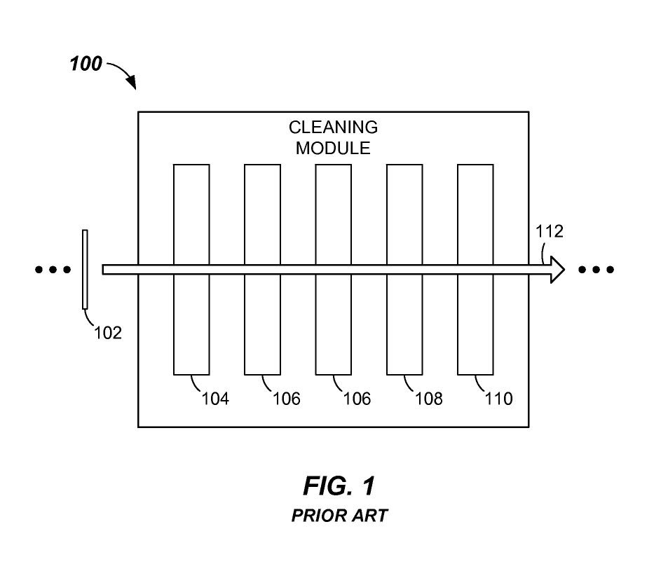

In one aspect, a control assembly may include a linkage arm configured to be coupled to a positioning assembly of a cleaning unit. The linkage arm may be extendable and retractable to cause, in some embodiments, the positioning assembly to move a pair of scrubber brush assemblies away from and into contact with a substrate positioned between the pair of scrubber brush assemblies. The control assembly may also include a load cell sensor that may sense a force on the linkage arm. The control assembly may further include a motor to drive the linkage arm to extend or retract. Data from the load cell sensor may be processed by a controller to direct the motor to adjust the extended or retracted position of the linkage arm to adjust the position of the scrubber brush assemblies relative to the substrate being cleaned. The control assembly may provide greater accuracy and control over the positioning of and force applied to the scrubber brush assemblies than conventional techniques using brush rotation motor torque data. Brush rotation motor torque data may not be an accurate indicator of scrubber brush assembly forces and/or position because of variables such as motor bearing seal friction, lip sealing friction, bearing friction, liquids on the substrate, friction on different substrate surfaces, and brush surface conditions. The greater accuracy and control provided by the control assembly may allow for a smaller gap between a pair of scrubbing brush assemblies during loading and unloading of substrates in a cleaning unit. In other aspects, methods of controlling a scrubber brush force are provided, as will be explained in greater detail below in connection with FIGS. 1-7.

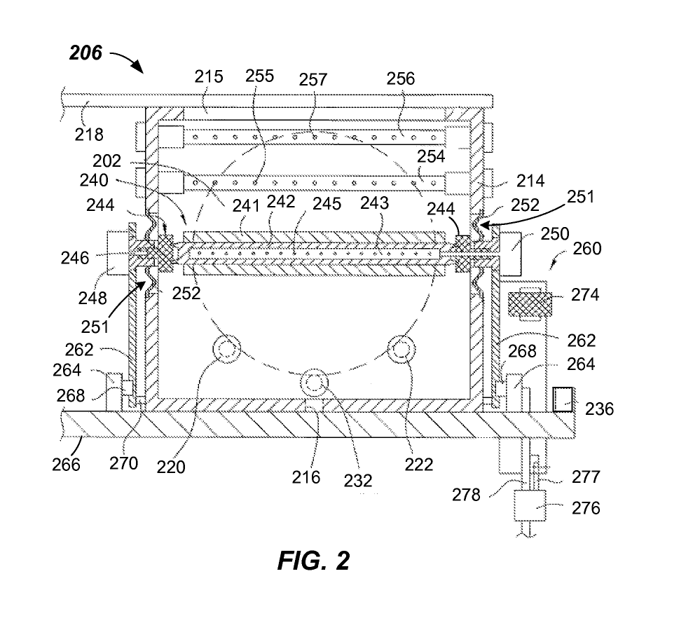

FIG. 1 illustrates a known cleaning module 100 in accordance with the prior art. Cleaning module 100 may be part of a chemical mechanical polishing (CMP) tool and may receive a partially-processed substrate 102 from a CMP polishing station of the CMP tool via one or more robots/transfer mechanisms (not shown). Substrate 102 may be a semiconductor wafer or other workpiece. Cleaning module 100 may include a megasonic cleaner unit 104, two brush box units 106, a jet cleaner unit 108, and a dryer unit 110. Cleaning module 100 may have other suitable numbers of units 104, 106, 108 and/or 110, and/or may additionally or alternatively have other suitable units than those shown. A transfer device (not shown) may move substrate 102 through cleaning module 100, as indicated by arrow 112. Megasonic cleaner unit 104 may be configured to perform a cleaning process using megasonic energy. The two brush box units 106 may each be configured to perform a cleaning process using mechanical contact via a scrubbing motion (described in more detail below in connection with FIGS. 2-4). Jet cleaner unit 108 may be configured to perform a cleaning process using pressurized liquid. And dryer unit 110 may be configured to perform a drying process to quickly dry a substrate after cleaning to remove bath residue and to prevent streaking and spotting caused by evaporation. After processing in dryer unit 110, substrate 102 may be returned to a CMP polishing station within the CMP tool or transported to another substrate processing tool. Cleaning module 100 may be part of, e.g., Reflexion® GT™ CMP System, by Applied Material, of Santa Clara, Calif.

FIGS. 2, 3A, 3B, and 4 show a brush box unit 206 in accordance with one or more embodiments. Brush box unit 206 may be configured to receive and clean a substrate 202 in a vertical position using scrubber brushes. In some embodiments, brush box unit 206 may include an enclosure 214 having a top opening 215 configured to allow a substrate to enter and exit there through via a substrate handler (not shown). Enclosure 214 may be configured to contain a cleaning solution therein and may include a drain 216. Brush box unit 206 may also include a sliding cover 218 configured to cover opening 215 to prevent cleaning solution from splashing out and outside particles from entering enclosure 214.

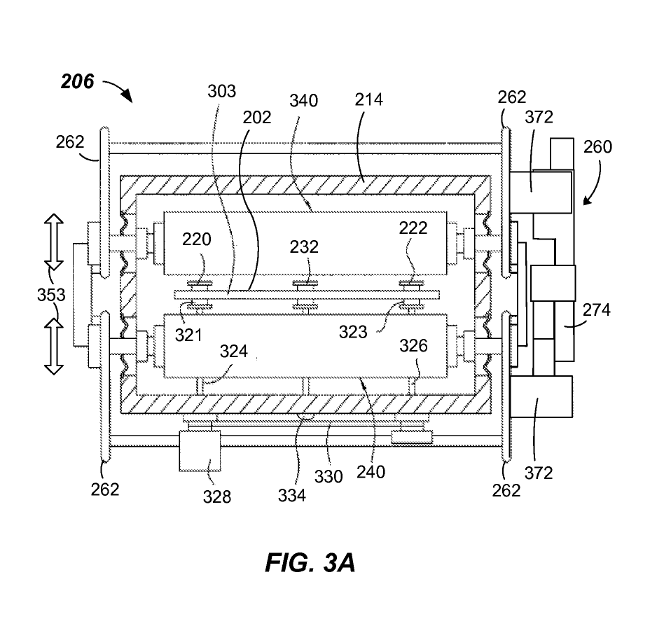

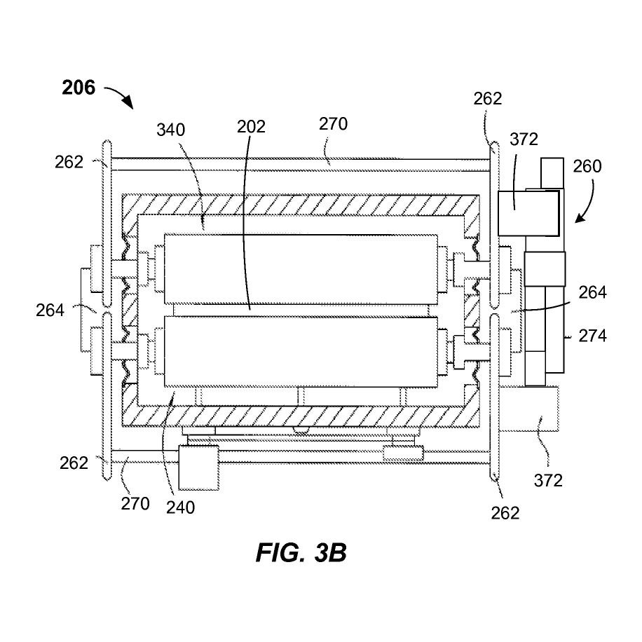

In some embodiments, brush box unit 206 may include two substrate rollers 220 and 222 positioned in a lower portion of enclosure 214. Substrate rollers 220 and 222 may each have a recessed area 321 and 323, respectively (see FIG. 3A), configured to receive a side edge 303 of substrate 202. Substrate rollers 220 and 222 may be coupled to respective driving axles 324 and 326. Driving axles 324 and 326 may be coupled to a driving mechanism 328, which may be a motor, configured to rotate substrate rollers 220 and 222. Driving axle 326 may be coupled to driving mechanism 328 via a belt assembly 330. In alternative embodiments, substrate rollers 220 and 222 may each be rotated by a different driving mechanism. During a cleaning process, substrate rollers 220 and 222 may rotate at substantially a same rate and may cause substrate 202 to rotate via friction.

Brush box unit 206 may, in some embodiments, include a sensor wheel 232 that may be positioned in a lower portion of enclosure 214. Substrate 202 may rest on sensor wheel 232. Sensor wheel 232 may be configured to rotate passively with substrate 202 and to transfer the rotation rate of substrate 202 to a rotation sensor 334 (see FIG. 3A). Rotation sensor 334 may be coupled to a system controller 236. Sensor wheel 232 may have other suitable configurations and positions.

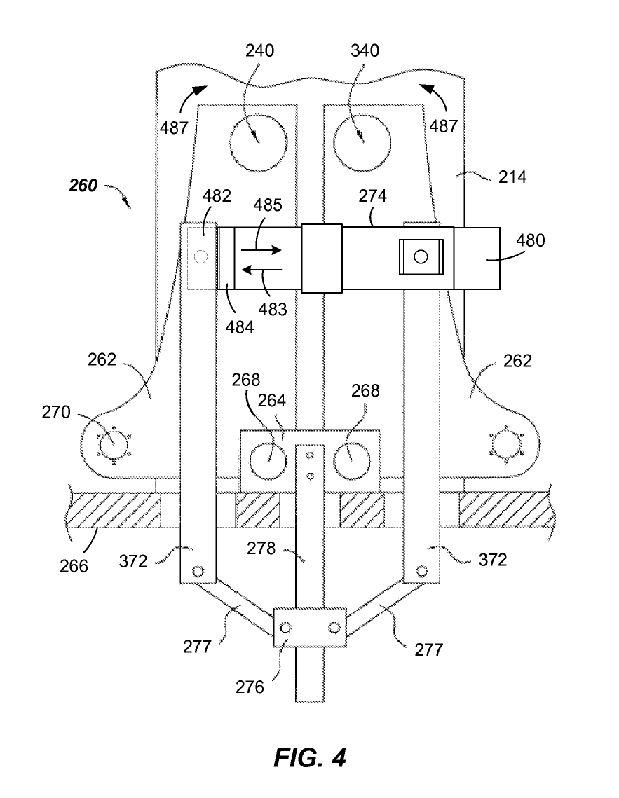

Brush box unit 206 may also include a pair of scrubber brush assemblies 240 and 340 (see FIGS. 3A, 3B, and 4) positioned above substrate rollers 220 and 222 in enclosure 214. Scrubber brush assemblies 240 and 340 may also be positioned to extend along opposite sides of substrate 202 and may be configured to movably contact substrate 202 during cleaning. Each scrubber brush assembly 240 and 340 may include a cylindrical scrubber brush 241 configured to contact substrate 202. Each cylindrical scrubber brush 241 may have surface cleaning features protruding therefrom (not shown) and may be mounted on a mandrel assembly 242. Each end of mandrel assembly 242 may be attached to a mounting shaft 244. One mounting shaft 244 may be coupled to a driving shaft 246 of a motor 248, which may be configured to rotate cylindrical scrubber brush 241 at a selected rotational speed. In some embodiments, motor 248 may be configured to rotate cylindrical scrubber brush 241 at a rotational speed of about 50 to 700 RPM. The other mounting shaft 244 may be connected to a cleaning solution supply 250, which may be fluidly coupled to an inner channel 243 of mandrel assembly 242. A plurality of openings 245 formed in mandrel assembly 242 may be configured to provide a cleaning solution received from cleaning solution supply 250 to cylindrical scrubber brush 241.

Scrubber brush assemblies 240 and 340 may be installed in brush box unit 206 via openings 251 formed in enclosure 214. A membrane seal 252 may be coupled around each end of scrubber brush assemblies 240 and 340 to seal respective openings 251. Membrane seals 252 allow scrubber brush assemblies 240 and 340 to move laterally (as indicated by arrows 353 in FIG. 3A) within openings 251.

In some embodiments, brush box unit 206 may also include a pair of cleaning solution spray bars 254 (only one is shown in FIG. 2) positioned on opposite sides of enclosure 214 and above scrubber brush assemblies 240 and 340. Other embodiments may have more or less than two cleaning solution spray bars 254. Cleaning solution spray bars 254 may be configured to spray cleaning solution via a plurality of nozzles 255 toward each side of substrate 202 during a cleaning process. Nozzles 255 may be evenly distributed along cleaning solution spray bar 254. Other embodiments may have other suitable numbers and configurations of nozzles 255.

In some embodiments, brush box unit 206 may further include a pair of water spray bars 256 (only one is shown in FIG. 2) positioned on opposite sides of enclosure 214 and above the cleaning solution spray bars 254. Other embodiments may have more or less than two water spray bars 256. Water spray bars 256 may be configured to spray deionized water or a chemical via a plurality of spraying nozzles 257 toward each side of substrate 202 as substrate 202 is being transferred into and/or out of enclosure 214. Nozzles 257 may be evenly distributed along water spray bar 256. Other embodiments may have other suitable numbers and configurations of nozzles 257.

Brush box unit 206 may include, in some embodiments, a positioning assembly 260 configured to move scrubber brush assemblies 240 and 340 relative to substrate 202. For example, FIG. 3A illustrates scrubber brush assemblies 240 and 340 in a retracted position (i.e., moved away from substrate 202), while FIG. 3B illustrates scrubber brush assemblies 240 and 340 in a cleaning position (i.e., moved towards and in contact with substrate 202). FIG. 4 illustrates a side view of positioning assembly 260.

Each scrubber brush assembly 240 and 340 may extend through membrane seal 252 and may be coupled to two pivoting plates 262 on opposite ends. Pivoting plates 262 are movably coupled to a mounting block 264 that may be secured to a supporting frame 266. Each pivoting plate 262 may be pivotable about a pivoting joint 268. The two pivoting plates 262 coupled to each of scrubber brush assembles 240 and 340 may be coupled to each other via a synchronizing bar 270 configured to synchronize the movement of the two pivoting plates 262.

As shown in FIGS. 3A, 3B, and 4, each pivoting plate 262 on one side of brush box unit 206 (i.e., the right side as shown) may be coupled to an actuating arm 372. A control assembly 274 may be coupled between the two actuating arms 372 in accordance with one or more embodiments. Control assembly 274 may be configured, in some embodiments, to linearly extend and retract to move actuating arms 372 relative to each other. A sliding block 276 (best shown in FIG. 4) may also be coupled between the two actuating arms 372. Each actuating arm 372 may be connected to sliding block 276 via a link 277. A vertical track 278 may be coupled to mounting block 264. Sliding block 276 may be configured to slide vertically along vertical track 278.

During a cleaning process, control assembly 274 may extend or retract to move actuating arms 372 relative to each other. The motion of actuating arms 372 may be restrained by links 277 and sliding block 276 to result in substantially symmetric motion. The motion of actuating arms 372 may cause pivoting plates 262 to pivot about pivoting joint 268, which may cause scrubber brush assemblies 240 and 340 to move in a symmetric manner. At the same time, synchronizing bars 270 may pivot about pivoting joints 268 to transfer motion of pivoting plates 262 from one side of enclosure 214 to the other side and, thus, synchronize the motion of pivoting plates 262 on the opposite ends of scrubber brush assemblies 240 and 340.

Referring to FIG. 4, control assembly 274 may include a motor 480 electrically coupled to system controller 236. Motor 480 may be electrically coupled to system controller 236 in any suitable manner (e.g., wired or wireless). Motor 480 may be configured to extend and retract a linkage arm 482 (shown in dashed line) of control assembly 274 in the direction of arrows 483 and 485, respectively, in precise, measured movements. After substrate 202 is loaded into brush box unit 206, motor 480 may be directed by system controller 236 to retract linkage arm 482 in the direction of arrow 485 to pull actuating arms 372 towards each other, which in turn may cause pivoting plates 262 to pivot about pivoting joint 268 in the direction of arrows 487. This movement of pivoting plates 262 may cause scrubber brush assemblies 240 and 340 to move into contact with substrate 202, as shown in FIG. 3B.

Control assembly 274 may also include a load cell sensor 484 mechanically coupled to linkage arm 482 and electrically coupled to system controller 236. Load cell sensor 484 may be electrically coupled to system controller 236 in any suitable manner (e.g., wired or wireless). Load cell sensor 484 may be a transducer configured to sense a force on linkage arm 482 and to convert that force into one or more electrical signals that are transmitted to system controller 236. As substrate 202 is cleaned in brush box unit 206, a force between substrate 202 and a scrubber brush 241 may be transferred via positioning assembly 260 to linkage arm 482, which may be sensed by load cell sensor 484 and transmitted to system controller 236 for processing. In response thereto, system controller 236 may transmit one or more control signals to motor 480, which may respond by adjusting the position of linkage arm 482, either by retracting or extending, to effect a change in the position of scrubber brush assemblies 240 and 340 relative to substrate 202. For example, if a sensed force is less than a threshold amount, which may indicate insufficient scrubbing pressure against the substrate, system controller 236 may direct motor 480 to retract linkage arm 482 slightly in the direction of arrow 485 to move scrubber brush assemblies 240 and 340 slightly more toward substrate 202 to increase scrubbing pressure against substrate 202. Similarly, if a sensed force is greater than a threshold amount, which may indicate too much scrubbing pressure against the substrate, system controller 236 may direct motor 480 to extend linkage arm 482 slightly in the direction of arrow 483 to move scrubber brush assemblies 240 and 340 slightly away from substrate 202 to decrease scrubbing pressure against the substrate.

In other embodiments, control assembly 274 and/or positioning assembly 260 may be configured to operate such that the movements described above may cause opposite movements of scrubber brush assemblies 240 and 340. That is, in other embodiments, retracting linkage arm 482 may cause scrubber brush assemblies 240 and 340 to move away from substrate 202, while extending linkage arm 482 may cause scrubber brush assemblies 240 and 340 to move toward substrate 202.

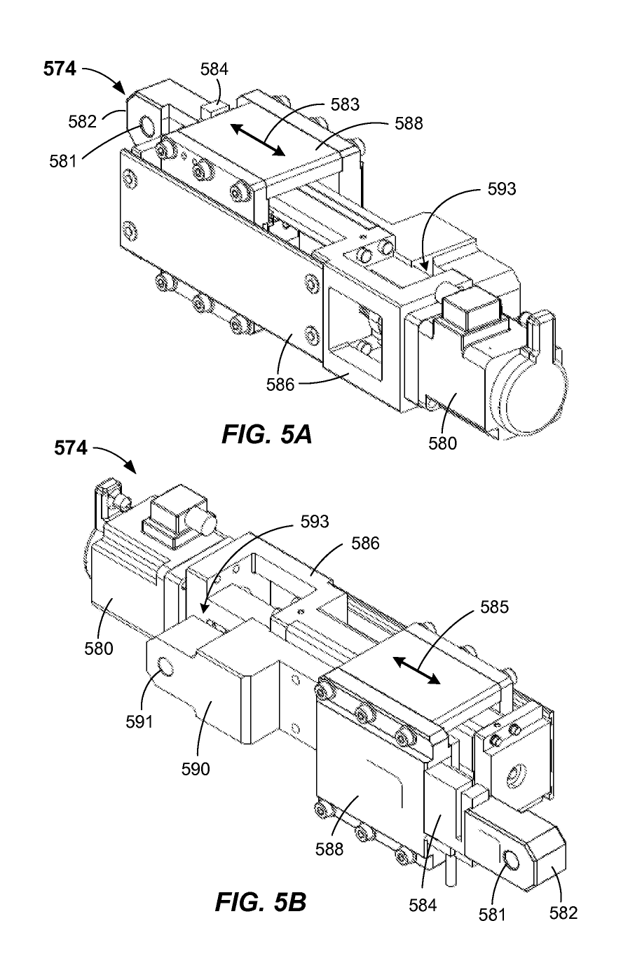

FIGS. 5A and 5B show a control assembly 574 in accordance with one or more embodiments. Control assembly 574 may be used in a CMP cleaning unit, such as brush box unit 206, or other suitable cleaning unit. Control assembly 574 may include a linkage arm 582 configured to extend and retract in the directions of arrows 583 and 585. Linkage arm 582 may be configured to be coupled to a positioning assembly of a cleaning unit, such as, e.g., positioning assembly 260 of brush box unit 206. In some embodiments, linkage arm may have a through-hole 581, which may be threaded, configured to receive a mechanical fastener for coupling to, e.g., an actuating arm 372 of positioning assembly 260.

Control assembly 574 may also include a load cell sensor 584 coupled to linkage arm 582. In some embodiments, load cell sensor 584 may be coupled to linkage arm 582 with mechanical fasteners (not shown), such as, e.g., a screw or bolt inserted through corresponding holes (not shown) in load cell sensor 584 and linkage arm 582. In other embodiments, load cell sensor 584 may be mechanically coupled to linkage arm 582 in any suitable manner. Load cell sensor 584 may be configured to be electrically coupled to a controller, such as, e.g., system controller 236 of brush box unit 206. Load cell sensor 584 may also be configured to sense a force on linkage arm 582, and to convert that sensed force to one or more electrical signals. The one or more electrical signals may be transmitted by load cell sensor 584 to a controller, such as, e.g., system controller 236.

Control assembly 574 may further include a motor 580 configured to drive linkage arm 582 to extend and retract in precise, measured movements. Motor 580 may be coupled to a main member 586. For example, motor 580 may be mounted to main member 586 with mechanical fasteners (not shown). In some embodiments, main member 586 may be a single structural part and, in other embodiments, may be an assembly of various structural parts. Motor 580 may also be coupled to a slider mechanism 588, which may be slidingly coupled to main member 586. Slider mechanism 588 may also be mechanically coupled to load cell sensor 584. In some embodiments, slider mechanism 588 may be a single structural part and, in other embodiments, may be an assembly of various structural parts. Under control of motor 580, slider mechanism 588 may be configured to extend and retract the mechanically coupled load cell sensor 584 and linkage arm 582 in the direction of arrows 583 and 585.

Control assembly 574 may still further include a linkage member 590 mechanically coupled to main member 586. Linkage member 590 may be mechanically coupled to main member 586 in any suitable manner (e.g., with fasteners, welding, etc.). In some embodiments, linkage member 590 may be an integral part of main member 586. Linkage member 590 may be configured to be coupled to a positioning assembly of a cleaning unit, such as, e.g., positioning assembly 260 of brush box unit 206. In some embodiments, linkage member 590 may have a through-hole 591, which may be threaded, configured to receive a mechanical fastener for coupling to, e.g., an actuating arm 372 of positioning assembly 260. An actuating arm 372 or the like may be received through a spacing 593 between linkage member 590 and main member 586.

In some embodiments, linkage arm 582, main member 586, slider mechanism 588, and linkage member 590 may have other suitable configurations than those shown in FIGS. 5A and 5B. Any suitable materials may be used to construct linkage arm 582, main member 586, slider mechanism 588, and linkage member 590, such as, e.g., PET, PEEK, or Delrin®. Linkage arm 582, main member 586, slider mechanism 588, and linkage member 590 may be mechanically coupled to each other as described above in any suitable manner. In some embodiments, control assembly 574 may have more or less numbers and/or combinations of suitable structural parts in addition or alternative to linkage arm 582, main member 586, slider mechanism 588, and/or linkage member 590.

In some embodiments, load cell sensors 482 and/or 582 may be a model SMA-40, by Interface, Inc., of Scottsdale, Ariz., packaged in an adaptor made from, e.g., PET, configured to be coupled in control assembly 274 and/or 574 as shown and described herein. Other suitable load cell sensors may alternatively be used in some embodiments.

In some embodiments, motors 480 and/or 580 may be a brushless DC motor with one or more of the following ratings: voltage of 200V, torque of 100 NM, speed of 1000 RPM, and power of 1500 W. In some embodiments, motors 480 and/or 580 may drive respective linkage arm 482 and/or 582 at a speed of about 4.0 mm/0.1 seconds. In some embodiments, motors 480 and/or 580 may be, e.g., a model R2AA04003FXPOOM, by Sanyo Denki America, Inc., of Torrance, Calif. Other suitable motors may alternatively be used in some embodiments.

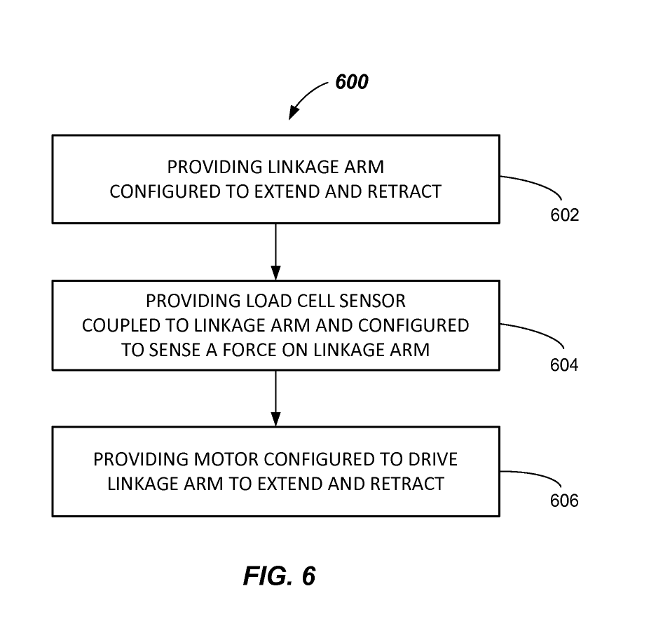

FIG. 6 illustrates a method 600 of controlling a scrubber brush force in accordance with one or more embodiments. At process block 602, method 600 may include providing a linkage arm configured to extend and retract. For example, referring to FIGS. 4, 5A, and 5B, the linkage arm may be linkage arm 482 or 582, which may be configured to extend and retract in the directions indicated by, e.g., arrows 483, 487, 583, and 587.

At process block 604, a load cell sensor coupled to the linkage arm and configured to sense a force on the linkage arm may be provided. For example, referring again to FIGS. 4, 5A, and 5B, the load cell sensor may be load cell sensor 484 or 584. As shown in FIG. 4, load cell sensor 484 may be coupled to linkage arm 482 and configured to sense a force on linkage arm 482, while load cell sensor 585, shown in FIGS. 5A and 5B, may be coupled to linkage arm 582 and configured to sense a force on linkage arm 582.

At process block 606, method 600 may include providing a motor configured to drive the linkage arm to extend and retract. In some embodiments, the motor may be motor 480 of FIG. 4 or motor 580 of FIGS. 5A and 5B.

The above process blocks of method 600 may be executed or performed in an order or sequence not limited to the order and sequence shown and described. For example, in some embodiments, any of process blocks 602, 604, and/or 606 may be performed before, after, or simultaneously with any other of process blocks 602, 604, and/or 606.

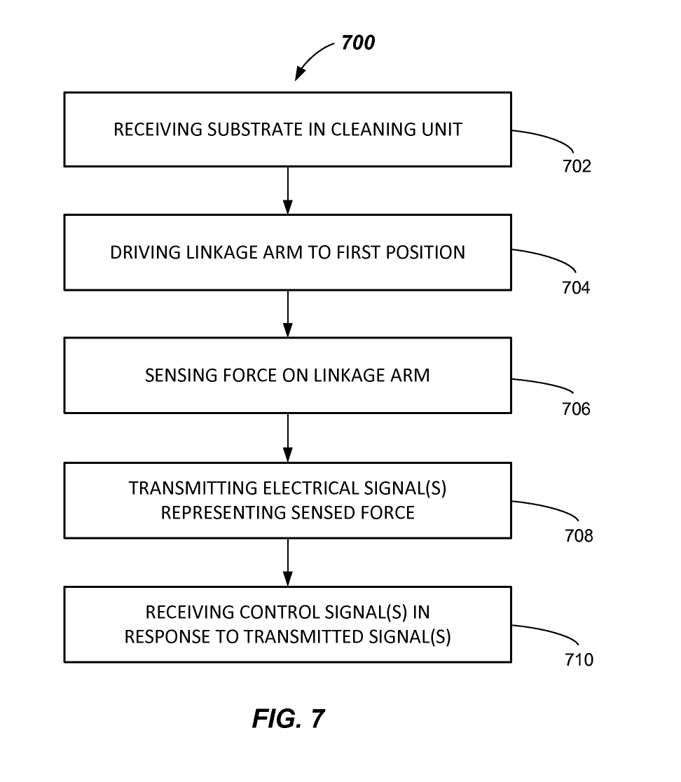

FIG. 7 illustrates another method 700 of controlling a scrubber brush force in accordance with one or more embodiments. At process block 702, method 700 may include receiving a substrate in a cleaning unit. For example, referring to FIGS. 2, 3A and 4, the received substrate may be substrate 202 and the cleaning unit may be brush box unit 206. Control assembly 274 may extend linkage arm 482 to cause scrubber brush assemblies 240 and 340 to move apart. Substrate 202 may be received in enclosure 214 through top opening 215 via a substrate handler.

At process block 704, a linkage arm may be driven to a first position configured to position a scrubber brush against the received substrate. For example, referring to FIGS. 3B and 4, linkage arm 482 may be retracted to a first position to pull actuating arms 372 towards each other, which in turn may cause pivoting plates 262 to pivot about pivoting joint 268 in the direction of arrows 487. This movement of pivoting plates 262 may cause scrubber brushes 241 of scrubber brush assemblies 240 and 340 to be positioned against substrate 202.

At process block 706, method 700 may include sensing a force on the linkage arm. In some embodiments, e.g., load cell sensor 484 of FIG. 4 may sense a force on linkage arm 482 transferred thereto by scrubber brush assemblies 240 and 340 as they are positioned against substrate 202 during a cleaning process.

At process block 708, method 700 may include transmitting one or more electrical signals representing the force sensed on the linkage arm. For example, in some embodiments, load cell sensor 484 may transmit one or more electrical signals representing the force sensed on the linkage arm 482 to system controller 236.

At process block 710, one or more control signals may be received in response to the transmitting of the one or more electrical signals in process block 710. For example, in some embodiments, motor 480 of FIG. 4 may receive one or more control signals from system controller 236 in response to system controller 236 receiving and processing one or more electrical signals representing the force sensed on the linkage arm 482. The control signals may direct motor 480 to either retract or extend linkage arm 482 to adjust the positions of scrubber brush assemblies 240 and 340 relative to substrate 202.

The above process blocks of method 700 may be executed or performed in an order or sequence not limited to the order and sequence shown and described.

As used herein, “coupling” may refer to mechanical and/or electrical coupling as appropriate, and may refer to direct connections as well as those where other parts or components may intervene.

Persons skilled in the art should readily appreciate that the invention described herein is susceptible of broad utility and application. Many embodiments and adaptations of the invention other than those described herein, as well as many variations, modifications, and equivalent arrangements, will be apparent from, or reasonably suggested by, the invention and the foregoing description thereof, without departing from the substance or scope of the invention. For example, control assembly 274 or 574 may be used with positioning assemblies other than positioning assembly 260 and with other types of processing units in which a force applied to apparatus in contact with a workpiece needs to be monitored and/or controlled. Accordingly, while the invention has been described herein in detail in relation to specific embodiments, it should be understood that this disclosure is only illustrative and presents examples of the invention and is made merely for purposes of providing a full and enabling disclosure of the invention. This disclosure is not intended to limit the invention to the particular apparatus, devices, assemblies, systems, or methods disclosed, but, to the contrary, the intention is to cover all modifications, equivalents, and alternatives falling within the scope of the invention.

What is claimed is:

1. A control assembly for a cleaning unit, comprising:
a linkage arm configured to extend and retract and configured to be coupled to a positioning assembly of the cleaning unit;
a load cell sensor coupled to the linkage arm and configured to sense a force on the linkage arm, and
a motor configured to drive the linkage arm to extend and retract.

2. The control assembly of claim 1 wherein:
the load cell sensor is configured to transmit one or more electrical signals representing a sensed force to a controller; and
the motor is configured to receive one or more control signals from the controller in response to the controller receiving the one or more electrical signals from the load cell sensor, and is configured to adjust a position of the linkage arm by extending or retracting the linkage arm in accordance with the received one or more control signals.

3. The control assembly of claim 1 further comprising a slider mechanism coupled to the motor and to the load cell sensor, the slider mechanism configured to extend and retract the load cell sensor and the linkage arm under control of the motor.

4. The control assembly of claim 1 further comprising a main member, wherein the motor is coupled to the main member, and the slider mechanism is slidingly coupled to the main member.

5. The control assembly of claim 4 further comprising a linkage member coupled to the main member and configured to be coupled to the positioning assembly of the cleaning unit.

6. The control assembly of claim 1 wherein the motor is a brushless DC motor.

7. The control assembly of claim 1 wherein the motor is configured to drive the linkage arm at a speed of about 4.0 mm/0.1 seconds.

8. Apparatus for cleaning a substrate, comprising:
first and second scrubber brush assemblies configured to contact and clean opposite surfaces of a substrate positioned between the first and second scrubber brush assemblies;
a positioning assembly coupled to the first and second scrubber brush assemblies and configured to move the first and second scrubber brush assemblies away from and into contact with the substrate; and
the control assembly of claim 1 wherein the linkage arm is coupled to the positioning assembly.

9. The apparatus of claim 8 further comprising a controller coupled to the motor and to the load cell sensor, the controller configured to receive one or more electrical signals representing a sensed force from the load cell sensor and configured to transmit one or more control signals to the motor in response to processing the received one or more electrical signals.

10. A method of controlling a scrubber brush force, comprising:
providing a linkage arm configured to extend and retract;
providing a load cell sensor coupled to the linkage arm and configured to sense a force on the linkage arm; and
providing a motor configured to drive the linkage arm to extend and retract.

11. The method of claim 10 further comprising:
coupling the load cell sensor to a controller; and
coupling the motor to the controller.

12. The method of claim 10 further comprising coupling the linkage arm to a positioning assembly of a cleaning unit, wherein the positioning assembly is configured to position at least one scrubber brush assembly relative to a substrate to be cleaned.

13. The method of claim 10 further comprising providing a slider mechanism coupled to the load cell sensor and to the motor, the slider mechanism configured to extend and retract the load cell sensor and the linkage arm under control of the motor.

14. The method of claim 13 further comprising providing a main member, wherein the motor is coupled to the main member, and the slider mechanism is slidingly coupled to the main member.

15. The method of claim 14 further comprising providing a linkage member coupled to the main member and configured to be coupled to a positioning assembly of a cleaning unit, wherein the positioning assembly is configured to position at least one scrubber brush assembly relative to a substrate to be cleaned.

16. A method of controlling a scrubber brush force, comprising:
receiving a substrate in a cleaning unit;
driving a linkage arm to a first position configured to position a scrubber brush against the substrate;
sensing a force on the linkage arm with a load cell sensor;
transmitting one or more electrical signals representing the force sensed on the linkage arm; and
receiving one or more control signals in response to the transmitting the one or more electrical signals.

17. The method of claim 16 further comprising driving the linkage arm to a second position configured to reposition the scrubber brush against the substrate in response to receiving the one or more control signals.

18. The method of claim 16 wherein the driving comprises driving the linkage arm to the first position via a motor and slider mechanism.

19. The method of claim 16 wherein the sensing comprises sensing the force on the linkage arm with the load cell sensor mechanically coupled to the linkage arm.

20. The method of claim 16 wherein:
the transmitting comprises transmitting to a controller the one or more electrical signals representing the force sensed on the linkage arm; and
the receiving comprises receiving from the controller the one or more control signals in response to the transmitting the one or more electrical signals and to the controller processing the one or more electrical signals.
